(19) United States
(12) Patent Application Publication
(10) Pub. No.: US 2015/0372064 A1
(43) Pub. Date: Dec. 24, 2015

(54) DISPLAY DEVICE

(71) Applicant: SAMSUNG DISPLAY CO., LTD., Yongin-City (KR)

(72) Inventor: Jae Hoon KIM, Suwon-si (KR)

(21) Appl. No.: 14/532,435

(22) Filed: Nov. 4, 2014

(30) Foreign Application Priority Data
Jun. 23, 2014 (KR) 10-2014-0076510

(51) Int. Cl. H01L 27/32; G02F 1/1334; G02F 1/1343; G02F 1/137; G02F 1/1335

(52) U.S. Cl. CPC H01L 27/3232; G02F 1/137; G02F 1/133504; G02F 1/134309; G02F 1/1334; G02F 1/133526

(57) ABSTRACT

A display device includes a light scattering layer to scatter light from a light emitter. The light scattering layer includes a liquid crystal layer between a first electrode and a second electrode. The liquid crystal layer includes cholesteric liquid crystals which scatter light from the light emitter based on an intensity of an applied electric field.

### CROSS-REFERENCE TO RELATED APPLICATION

Korean Patent Application No. 10-2014-0076510, filed on Jun. 23, 2014, and entitled, “Display Device,” is incorporated by reference herein in its entirety.

### BACKGROUND

1. Field

One or more embodiments described herein relate to a display device.

2. Description of the Related Art

Various types of displays have been developed. Examples include liquid crystal displays, electrophoretic displays, organic light emitting displays, inorganic electroluminescent displays, field emission displays, surface-conduction electron-emitter displays, plasma displays, and cathode ray tube displays.

Organic light emitting displays generate images from pixels, each of which includes organic layers between an anode and cathode on a transparent substrate. The organic layers may include an emitting layer, a hole-injecting layer, a hole-transporting layer, an electron-transporting layer, and an electron-injecting layer. In operation, holes and electrons generated by the anode and the cathode combine in the emitting layer to form excitons. When the energy level of the excitons changes from an excited state to a ground state, light is emitted of a color corresponding to the changed energy level.

If the organic light-emitting display is of a bottom emission-type, light should be emitted from the emitting layer through the anode and the transparent substrate, for viewing by a viewer. However, the difference in refractive index between the organic layers, the anode, and the transparent substrate may cause light from the emitting layer to be trapped in the organic light-emitting display. For example, approximately 80% of light from the light emitting layer may be trapped in the organic light-emitting display.

### SUMMARY

In accordance with one embodiment, a display device including a light emitter; and a light scattering layer to scatter light from the light emitter, wherein the light scattering layer includes a liquid crystal layer between a first electrode and a second electrode, and wherein the liquid crystal layer includes cholesteric liquid crystals. The first and second electrodes of the light scattering layer may be coupled to a first power source.

The cholesteric liquid crystals may be placed in a focal conic state based on an electric field generated between the first and second electrodes, the electric field may be generated based on power from the first power source. Light from the light emitter may be scattered by different amounts based on an intensity of an electric field generated between the first and second electrodes, the electric field may be generated based on power from the first power source.

The light scattering layer may include a first passivation layer interposed between the first electrode and the liquid crystal layer; and a second passivation layer between the second electrode and the liquid crystal layer. At least one of the first passivation layer or the second passivation layer may include a plurality of sub-passivation layers which include different materials. The liquid crystal layer may include a polymer mixed with the cholesteric liquid crystals.

The light emitter may include an anode; a cathode over the anode; and an organic light emitting layer to emit light, the organic light emitting layer between the anode and the cathode. The anode and cathode may be coupled to a second power source.

The display device may include one or more lenses located on a path of light from the light emitter. The display device may include a substrate for the light emitter and the light scattering layer, wherein the one or more lenses directly contact at least one of the substrate, the first electrode, or the second electrode. The substrate may include one or more recesses, and the one or more lenses may be located on respective ones of the one or more recesses.

In accordance with another embodiment, a display device may include a light emitter; and a light scattering layer to scatter light from the light emitter, wherein the light scattering layer includes a liquid crystal layer which includes cholesteric liquid crystals, the liquid crystal layer coupled to an electric field applying unit, an electric field to be generated by the electric field applying unit to maintain the cholesteric liquid crystals in a focal conic state. The electric field may be control a degree to which light from the light emitter is scattered, where the degree to which the light is scattered may be based on an intensity of the electric field.

The display device may include a first electrode; a second electrode, wherein the liquid crystal layer is between the first and second electrodes, and wherein the first electrode and the second electrode are connected to the electric field applying unit. The light scattering layer may include a first passivation layer between the first electrode and the liquid crystal layer; and a second passivation layer between the second electrode and the liquid crystal layer.

In accordance with another embodiment, a display device includes a light emitter; and a light scattering layer to scatter light from the light emitter, wherein the light scattering layer includes a liquid crystal layer which includes cholesteric liquid crystals, the liquid crystal layer coupled to an electric field applying unit, an electric field generated by the electric field applying unit to control a degree to which the light from the light emitter is scattered based on an intensity of the electric field. The electric field may maintain the cholesteric liquid crystals in a focal conic state. The display device may include a first electrode; a second electrode, wherein the liquid crystal layer is between the first and second electrodes, and wherein the first electrode and the second electrode are connected to the electric field applying unit.

The light scattering layer may include a first passivation layer between the first electrode and the liquid crystal layer; and a second passivation layer between the second electrode and the liquid crystal layer.

In accordance with another embodiment, a pixel may include a light emitter; a pair of electrodes; and a liquid crystal layer including cholesteric liquid crystals between the pair of electrodes, wherein the cholesteric liquid crystals are to be placed in first state based on a first intensity of an applied electric field and are to be placed in a second state based on a second intensity of the applied electric field. The first state may be a focal conic state, and the second state may be a homeotropic or planar state.

### BRIEF DESCRIPTION OF THE DRAWINGS

Features will become apparent to those of skill in the art by describing in detail exemplary embodiments with reference to the attached drawings in which:

FIG. 1 illustrates an embodiment of a display device;

FIGS. 2-4 illustrate an example of the behavior of a liquid crystal layer; and

FIGS. 5-13 illustrate other embodiments of a display device.

### DETAILED DESCRIPTION

Example embodiments are described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art. In the drawings, the dimensions of layers and regions may be exaggerated for clarity of illustration. Like reference numerals refer to like elements throughout.

It will be understood that when an element or layer is referred to as being “on,” “connected to” or “coupled to” another element or layer, the element or layer can be directly on, connected or coupled to another element or layer or intervening elements or layers. In contrast, when an element is referred to as being “directly on,” “directly connected to” or “directly coupled to” another element or layer, there are no intervening elements or layers present. As used herein, connected may refer to elements being physically, electrically and/or fluidly connected to each other. Like numbers refer to like elements throughout. As used herein, the term “and/or” includes any and all combinations of one or more of the associated listed items.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the invention.

Spatially relative terms, such as “below,” “lower,” “under,” “above,” “upper” and the like, may be used herein for ease of description to describe the relationship of one element or feature to another element(s) or feature(s) as illustrated in the figures. It will be understood that the spatially relative terms are intended to encompass different orientations of the device in use or operation, in addition to the orientation depicted in the figures. For example, if the device in the figures is turned over, elements described as “below” or “beneath” relative to other elements or features would then be oriented “above” relative to the other elements or features. Thus, the exemplary term “below” can encompass both an orientation of above and below. The device may be otherwise oriented (rotated 90 degrees or at other orientations) and the spatially relative descriptors used herein interpreted accordingly.

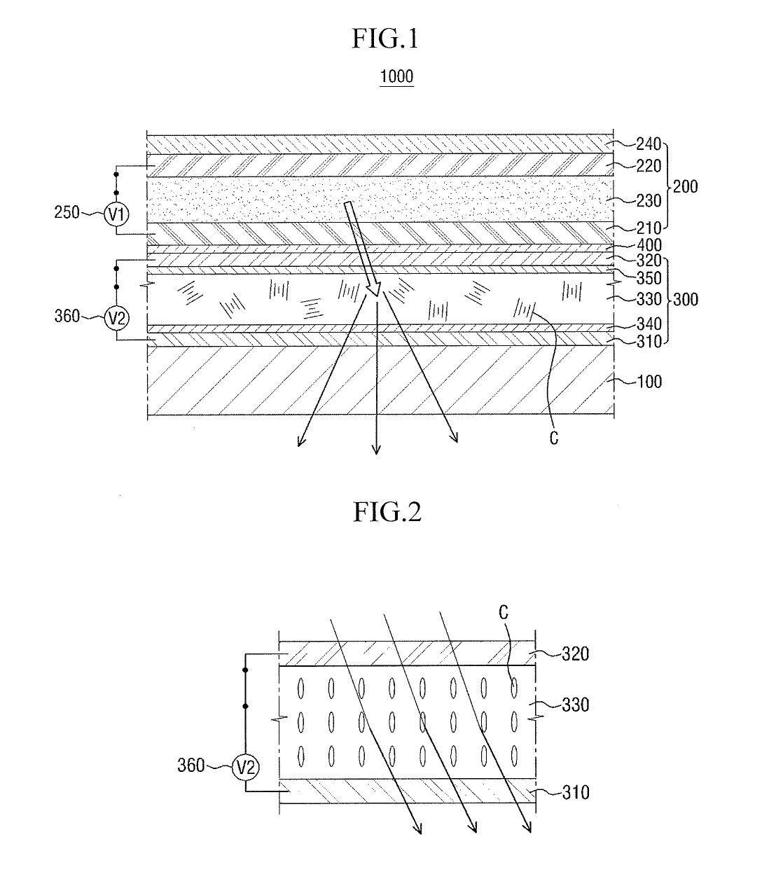

FIG. 1 illustrates an embodiment of a display device 1000 which includes a substrate 100, a display element 200, a light scattering member 300, and an adhesive layer 400. The display device may be a liquid crystal display, an electrophoretic display, an organic light emitting display, an inorganic electroluminescent display, a field emission display, a surface-conduction electron-emitter display, a plasma display, a cathode ray display, or another type of display.

The substrate 100 includes an insulating substrate made of a transparent material (e.g., glass) containing SiO₂. In another embodiment, the insulating substrate may be made of an opaque material. Also, the substrate 100 may be a flexible substrate that may be rolled, folded, bent, etc. The flexible substrate may be made of a plastic material having predetermined or superior heat resistance and durability. Examples include polyethylene ether phthalate, polyethylene naphthalate, polycarbonate, polyarylate, polyetherimide, polyethersulfone, polyimide, etc.

The display element 200 is on the substrate 100, and may be any element for displaying an image. For example, the display element 200 may be a single self-emitting display element such as an organic light-emitting display element corresponding to a pixel or sub-pixel. (In accordance with one or more embodiments, the terms pixel and sub-pixel may be used interchangeably). Alternatively, and the display element 200 may also be a complex of liquid crystals and a light source. In one embodiment, the display element 200 may emit light toward the substrate 100. In another embodiment, the display element 200 may emit light away from the substrate 100.

When the display device 1000 is, for example, an organic light emitting display, the display element 200 may include an anode 210, a cathode 220, an organic light-emitting layer 230, a capping layer 240, and a first power source 250.

The anode 210 is located on the substrate 100, and delivers holes to the organic light-emitting layer 230. The anode 210 may be made of a conductive material, for example, with a high work function. In one embodiment of FIG. 1, light is emitted in directions indicated by the arrows in FIG. 1. The display device 1000 in FIG. 1 is therefore a bottom emission-type device.

In this case, the anode 210 may be made of a material such as indium tin oxide (ITO), indium zinc oxide (IZO), zinc oxide (ZnO) or indium oxide (In₂O₃) or another transparent material, or may be made of a stacked layer of these materials. The anode 210 may be modified in various ways to have, for example, a structure including two or more layers formed using two or more different materials, for example, selected from the aforementioned materials. The anode 210 may be formed by a sputtering process using, e.g., a fine metal mask (FMM).

The cathode 220 is located on the anode 210, and delivers electrons to the organic light-emitting layer 230. The cathode 220 is made of a conductive material, for example, with a low work function. The cathode 220 may be made, for example, of Ag, Mg, Al, Pt, Pd, Au, Ni, Nd, Ir, Cr, Li, Ca, or another conductive material. As indicated, in this case, the display device 1000 of FIG. 1 may be a bottom emission-type device. The cathode 220 may include a reflective layer, and may be formed, for example, by a sputtering process using, e.g., an open mask.

The organic light-emitting layer 230 is between the anode 20 and the cathode 220. In response to an electric current supplied to the organic light-emitting layer 230, electrons and holes within the organic light-emitting layer 230 recombine to form excitons. Energy from the excitons generate light of a certain wavelength.

The organic light-emitting layer 230 may be made, for example, of a small molecular weight organic material or a polymer organic material. The organic light-emitting layer 230 may include, for example, all or a portion of a hole-injecting layer (HIL), a hole-transporting layer (HTL), a hole-blocking layer (HBL), an emitting layer (EML), an electron-transporting layer (ETL), an electron-injecting layer (EIL), and an electron-blocking layer (EBL).

The capping layer 240 is on the cathode 220, and serves to protect underlying layers. The capping layer 240 may be made, for example, of one or more of an inorganic material and an organic material. For example, the capping layer 240 may be made of an inorganic layer or an organic layer, or may be made of an organic layer that includes inorganic particles. Examples of inorganic materials that may be used in the capping layer 240 include silicon oxide and magnesium fluoride.

Examples of organic material that may be used in the capping layer 240 include a polymer, e.g., tris(8-hydroxyquinolinato)aluminum (Alq3), acrylic, polyimide, or polyamide. In other embodiments, the capping layer 240 may be made of various other materials.

The first power source 250 may be connected to the anode 210 and the cathode 220. The first power source 250 may supply an electric current to the organic light emitting layer 230. The first power source 250 may include a switching unit. Thus, the first power source 250 may be driven only when necessary or at predetermined times.

The light scattering member 300 is between the substrate 100 and the display element 200. The light scattering member 300 may scatter light emitted from the display element 200.

The light scattering member 300 may include a first electrode 310, a second electrode 320, a liquid crystal layer 330, a first passivation layer 340, a second passivation layer 350, and a second power source 360.

The first electrode 310 is on the substrate 100, e.g., in direct contact with the substrate 100. The first electrode 310 may be made, for example, of a transparent conductive oxide material, including but not limited to at least one of ITO or IZO.

The second electrode 320 is on the first electrode 310, and, for example, between the display element 200 and the first electrode 310. The second electrode 320 may be made, for example, of a transparent conductive oxide material, including but not limited to at least one of ITO or IZO. The second electrode 320 may be made of the same material as the first electrode 310, or a different material.

The liquid crystal layer 330 is between the first electrode 310 and the second electrode 320 and includes, for example, cholesteric liquid crystals C. Light emitted from the display element 200 is scattered by the liquid crystal layer 330.

The first passivation layer 340 is between the first electrode 310 and the liquid crystal layer 330. The first passivation layer 340 serves to protect the liquid crystal layer 330 from the first electrode 310. The first passivation layer 340 may include an insulating material, e.g., made of an organic or inorganic material. Alternatively, the first passivation layer 340 may include a stack of organic and inorganic layers.

The second passivation layer 350 is between the second electrode 320 and the liquid crystal layer 330. The second passivation layer 350 serves to protect the liquid crystal layer 330 from the second electrode 320. The second passivation layer 350 may include an insulating material, e.g., made of an organic or inorganic material. Alternatively, the second passivation layer 350 may include a stack of organic and inorganic layers. The second passivation layer 350 may also be made of the same material as the first passivation layer 340, but this is not necessary.

The second power source 360 is connected to the first electrode 310 and the second electrode 320. The second power source 360 generates an electric field between the first electrode 310 and the second electrode 320, e.g., the second power source 360 may be an electric field applying unit. The second power source 360 may include a switching unit. Thus, the second power source 360 may be driven only when necessary or at predetermined times. In addition, the second power source 360 may be driven independently from the first power source 250.

In one embodiment, when the first power source 250 is on, the second power source 360 may also be on. When the first power source 250 is off, the second power source 360 may also be off.

The adhesive layer 400 is between the display element 200 and the light scattering member 300. The adhesive layer 400 may attach the display element 200 and the light scattering member 300 to each other, while insulating the anode 210 of the display element 200 from the second electrode 320 of the light scattering member 300. The adhesive layer 400 may include, for example, of a photocurable adhesive. Additionally, or alternatively, the adhesive layer 400 may include a thermosetting adhesive.

FIGS. 2 through 4 are cross-sectional views illustrating an example of how the liquid crystal layer 330 operates. Referring to FIG. 2, when the second power source 360 applies a first predetermined (e.g., high-intensity) electric field between the first electrode 310 and the second electrode 320, the cholesteric liquid crystals C of the liquid crystal layer 330 are placed in a homeotropic state. In this state, the cholesteric liquid crystals C allow light to transmit through the liquid crystal layer 330. The direction of light propagation may change slightly due to a refractive index of the liquid crystal layer 330.

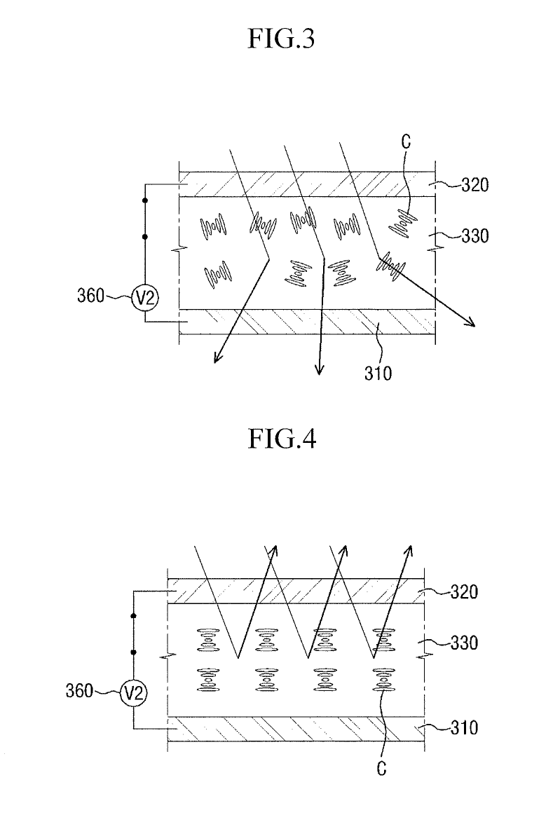

Referring to FIG. 3, when the second power source 360 applies a second predetermined (e.g., medium-intensity) electric field between the first electrode 310 and the second electrode 320, the cholesteric liquid crystals C of the liquid crystal layer 330 are placed in a focal conic state. The cholesteric liquid crystals C in the focal conic state scatter light irradiated to the liquid crystal layer 330.

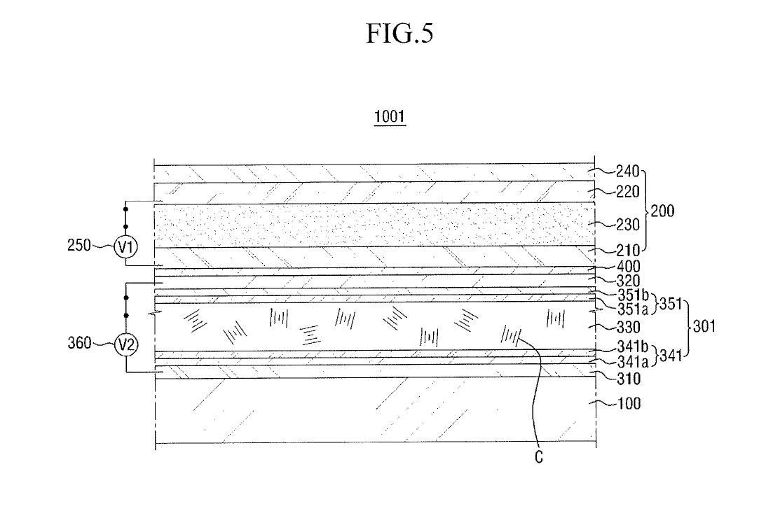

Referring to FIG. 4, when the second power source 360 applies a third predetermined electric field (e.g., low-intensity or no electric field) between the first electrode 310 and the second electrode 320, the cholesteric crystals C of the liquid crystal layer 330 are placed in a planar state. The cholesteric liquid crystals C in the planar state reflect light irradiated to the liquid crystal layer 330, e.g., the cholesteric liquid crystals C in the planar state function as a Bragg reflective layer.

As described above, the cholesteric liquid crystals C may be placed in three states based on the intensity of an electric field applied to the liquid crystal layer 330. For example, the display device 1000 may maintain the cholesteric liquid crystals C in the focal conic state by applying a medium-intensity electric field to the liquid crystal layer 330. Accordingly, light emitted from the organic light-emitting layer 230 is scattered in different directions (or different angles) as it passes through the liquid crystal layer 330, which includes the cholesteric liquid crystals C in the focal conic state (indicated by arrows of FIG. 1). As a result, the amount of light trapped in the display device 1000 may be substantially reduced. For example, the liquid crystal layer 330 including the cholesteric liquid crystals C in the focal conic state may prevent a total reflection of light emitted from the organic light-emitting layer 230 within the display device 1000.

Furthermore, the second power source 360 of the display device 1000 controls the degree of light scattering by adjusting the intensity of an electric field applied to the liquid crystal layer 330. To scatter a high degree of light, the second power source 360 applies an electric field, less intense than an electric field of reference intensity, to the liquid crystal layer 330. To scatter a low degree of light, the second power source 360 applies an electric field, more intense than the electric field of the reference intensity, to the liquid crystal layer 330. Additionally, or alternatively, the second power source 360 may adjust the intensity of the electric field applied to the liquid crystal layer 330 based on the intensity of external illumination.

FIG. 5 illustrates another embodiment of a display device 1001 which includes a first passivation layer 341 between a first electrode 310 and a liquid crystal layer 330, and a second passivation layer 351 between a second electrode 320 and the liquid crystal layer 330. At least one of the first passivation layer 341 or the second passivation layer 351 may include a plurality of sub-passivation layers 341a and 341b or 351a and 351b made of different materials. The sub-passivation layers 341a and 341b or 351a and 351b may be made, for example, of an organic material, an inorganic material, or a combination of the same.

In one embodiment, the first passivation layer 341 may include a first sub-passivation layer 341a adjacent to the first electrode 310 and a second sub-passivation layer 341b adjacent to the liquid crystal layer 330. The first sub-passivation layer 341a and the second sub-passivation layer 341b may be made of different materials. In addition, the second passivation layer 351 may include a third sub-passivation layer 351a adjacent to the liquid crystal layer 330 and a fourth sub-passivation layer 351b adjacent to the second electrode 320. The third sub-passivation layer 351a and the fourth sub-passivation layer 351b may be made of different materials.

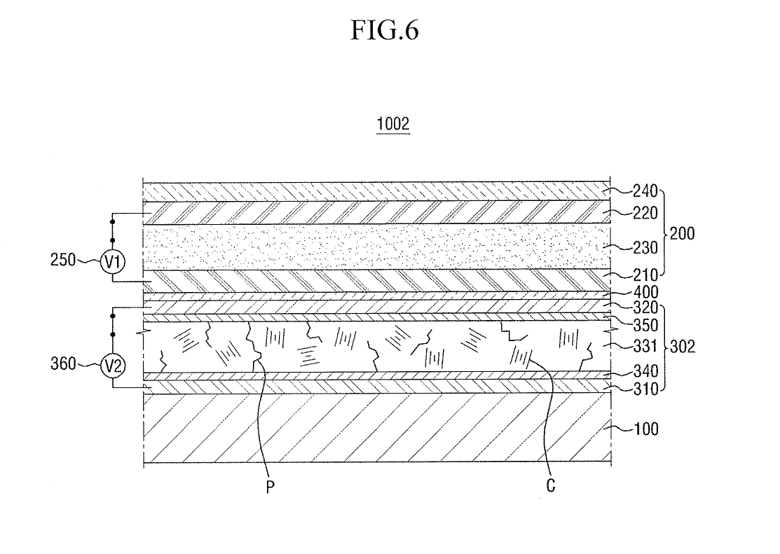

FIG. 6 illustrates another embodiment of a display device 1002. Referring to FIG. 6, a liquid crystal layer 331 of a light scattering member 302 may include a polymer P mixed with cholesteric liquid crystals C. The polymer P may help the cholesteric liquid crystals C remain in a focal conic state. In one embodiment, the polymer P may include a plurality of photopolymerization monomers bonded to each other. The monomers may be bonded to each other to form the polymer P when the cholesteric liquid crystals C are in the focal conic state, for example, in response to a medium-intensity electric field applied to the liquid crystal layer 331.

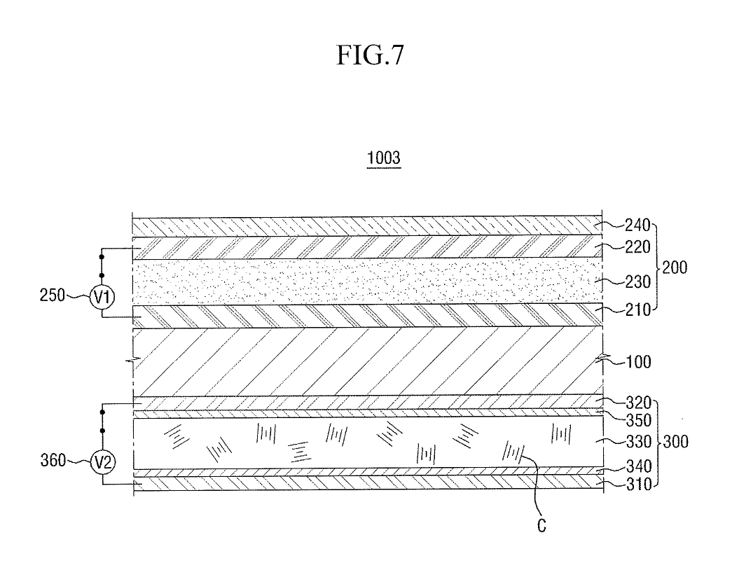

FIG. 7 illustrates another embodiment of a display device 1003. Referring to FIG. 7, a light scattering member 300 may be located on a bottom surface of a substrate 100. e.g., the light scattering member 300 may face the display element 200 with the substrate 100 interposed therebetween. In this embodiment, the adhesive layer may be omitted.

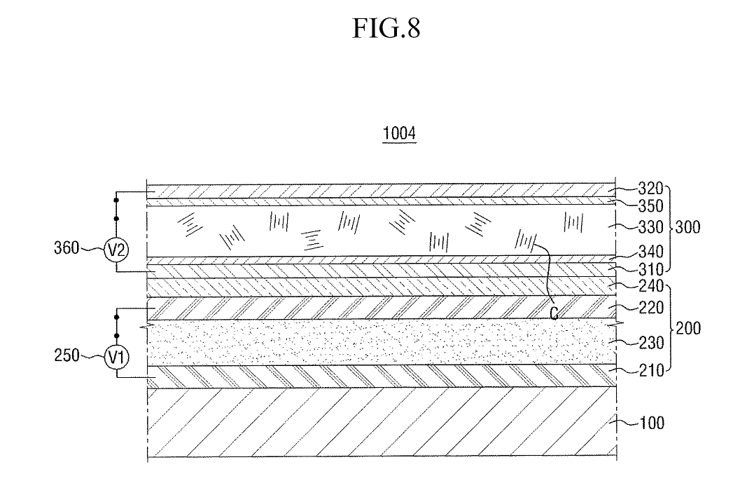

FIG. 8 illustrates another embodiment of a display device 1004. Referring to FIG. 8, a light scattering member 300 may be formed on a capping layer 240 of the display element 200, e.g., the light scattering member 300 may face the substrate 100 with the display element 200 interposed therebetween. In this embodiment, the adhesive layer may be omitted.

The display device 1004 may be, for example, a top emission-type display device. That is, light emitted from an organic light-emitting layer 230 may travel toward a cathode 220. Thus, an anode 210 may further include a reflective layer made of a conductive material including but not limited to Ag, Mg, Al, Pt, Pd, Au, Ni, Nd, Ir, Cr, Li or Ca. The cathode 220 may be made of a semi-transmissive layer, or transmissive layer, in this embodiment.

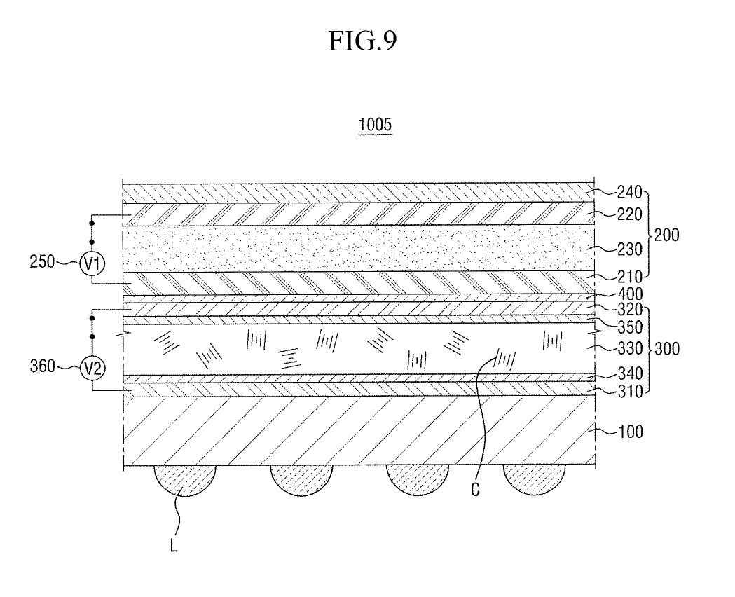

FIG. 9 illustrates another embodiment of a display device 1005. Referring to FIG. 9, the display device 1005 may include one or more lenses L. For example, the display device 1005 may be the display device 1000 of FIG. 1 having one or more lenses L formed on a bottom surface of the substrate 100. The one or more lenses L may directly contact the bottom surface of the substrate 100. For example, the lenses L may be located on the path of light emitted from an organic light-emitting layer 230. Like the light scattering member 300, the lenses L may scatter light emitted from the organic light-emitting layer 230. The lenses L may be made, for example, of an organic material, an inorganic material, or a combination of the same, and may have a refractive index in a predetermined range, e.g., approximately 1.5 to 1.8.

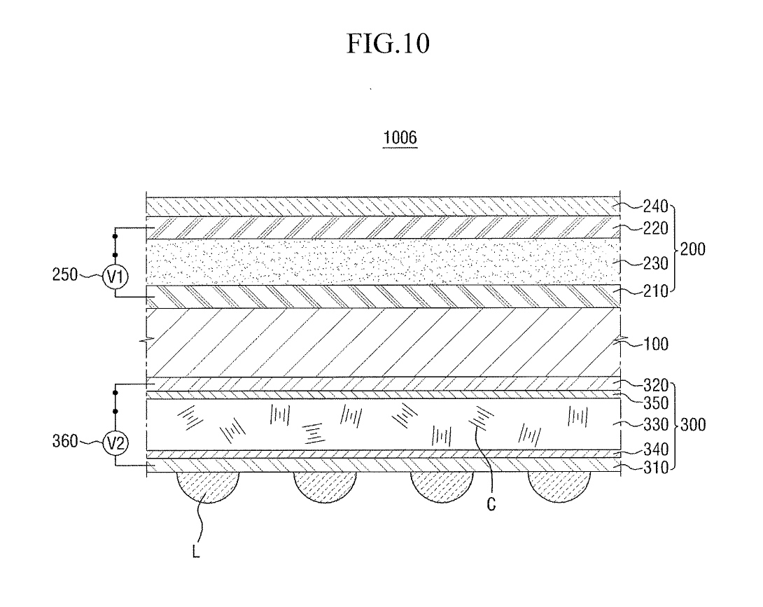

FIG. 10 illustrates another embodiment of a display device 1006. Referring to FIG. 10, the display device 1006 includes one or more lenses L. The display device 1006 of FIG. 10 may be the display device 1003 of FIG. 7 having the one or more lenses L formed on a first electrode 310. The lenses L may directly contact the first electrode 310.

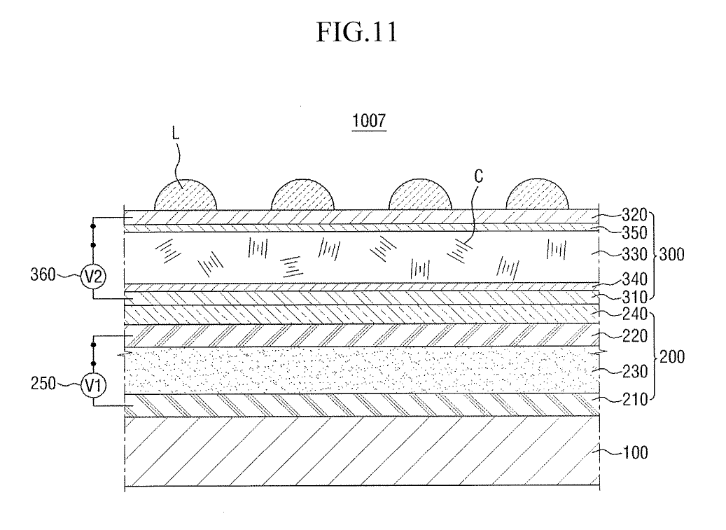

FIG. 11 illustrates another embodiment of a display device 1007. Referring to FIG. 11, the display device 1007 includes one or more lenses L. The display device 1007 of FIG. 11 may be the display device 1004 of FIG. 8 having the lenses L formed on a second electrode 320. The lenses L may directly contact the second electrode 320.

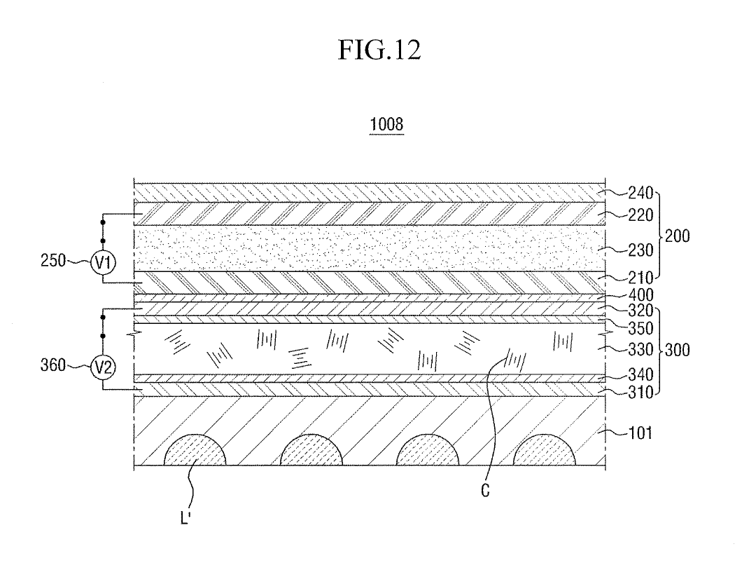

FIG. 12 illustrates another embodiment of a display device 1008. Referring to FIG. 12, substrate 101 may include one or more recesses, and lenses L′ may be located on the recesses, respectively. For example, a surface of the substrate 101 may be etched by an etching process to form the recesses, and the material that forms the lenses L′ may be inserted into or placed on the recesses, to thereby form the lenses L′ in the substrate 101.

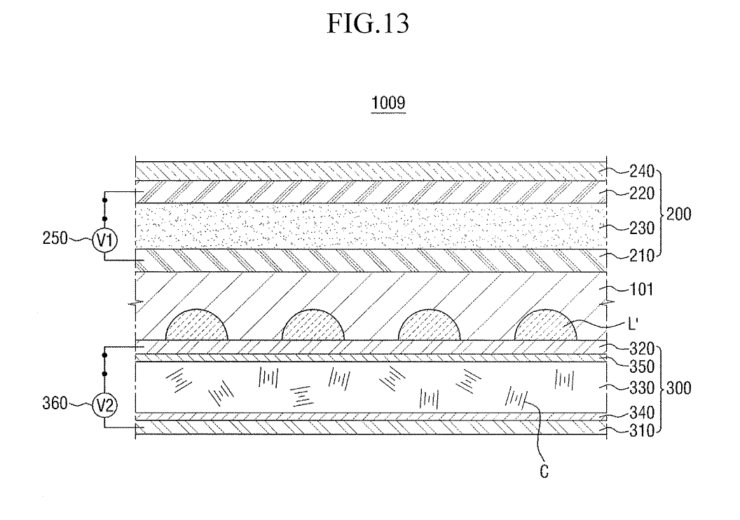

FIG. 13 illustrates another embodiment of a display device 1009. Referring to FIG. 13, as in the embodiment of FIG. 12, substrate 101 may include one or more recesses, and lenses L′ may be located in or on the recesses, respectively. The display device 1009 of FIG. 13 may be formed, for example, by processing the display device 1003 of FIG. 7.

Example embodiments have been disclosed herein, and although specific terms are employed, they are used and are to be interpreted in a generic and descriptive sense only and not for purpose of limitation. In some instances, as would be apparent to one of skill in the art as of the filing of the present application, features, characteristics, and/or elements described in connection with a particular embodiment may be used singly or in combination with features, characteristics, and/or elements described in connection with other embodiments unless otherwise indicated. Accordingly, it will be understood by those of skill in the art that various changes in form and details may be made without departing from the spirit and scope of the present invention as set forth in the following claims.

What is claimed is:

1. A display device, comprising:
a light emitter; and
a light scattering layer to scatter light from the light emitter, wherein the light scattering layer includes a liquid crystal layer between a first electrode and a second electrode, and wherein the liquid crystal layer includes cholesteric liquid crystals.

2. The device as claimed in claim 1, wherein the first and second electrodes of the light scattering layer are coupled to a first power source.

3. The device as claimed in claim 2, wherein the cholesteric liquid crystals are to be placed in a focal conic state based on an electric field generated between the first and second electrodes, the electric field to be generated based on power from the first power source.

4. The device as claimed in claim 2, wherein light from the light emitter is scattered by different amounts based on an intensity of an electric field generated between the first and second electrodes, the electric field to be generated based on power from the first power source.

5. The device as claimed in claim 1, wherein the light scattering layer includes:
a first passivation layer interposed between the first electrode and the liquid crystal layer; and
a second passivation layer between the second electrode and the liquid crystal layer.

6. The device as claimed in claim 5, wherein at least one of the first passivation layer or the second passivation layer includes a plurality of sub-passivation layers which include different materials.

7. The device as claimed in claim 1, wherein the liquid crystal layer includes a polymer mixed with the cholesteric liquid crystals.

8. The device as claimed in claim 1, wherein the light emitter includes:
an anode;
a cathode over the anode; and
an organic light emitting layer to emit light, the organic light emitting layer between the anode and the cathode.

9. The device as claimed in claim 8, wherein the anode and cathode are coupled to a second power source.

10. The device as claimed in claim 1, further comprising:
one or more lenses located on a path of light from the light emitter.

11. The device as claimed in claim 10, further comprising:
a substrate for the light emitter and the light scattering layer,
wherein the one or more lenses directly contact at least one of the substrate, the first electrode, or the second electrode.

12. The device as claimed in claim 11, wherein the substrate includes one or more recesses, and wherein the one or more lenses are located on respective ones of the one or more recesses.

13. A display device, comprising:
a light emitter; and
a light scattering layer to scatter light from the light emitter, wherein the light scattering layer includes a liquid crystal layer which includes cholesteric liquid crystals, the liquid crystal layer coupled to an electric field applying unit, an electric field to be generated by the electric field applying unit to maintain the cholesteric liquid crystals in a focal conic state.

14. The device as claimed in claim 13, wherein the electric field is to control a degree to which light from the light emitter is scattered, the degree to which the light is scattered based on an intensity of the electric field.

15. The device as claimed in claim 13, further comprising:
a first electrode;
a second electrode,
wherein the liquid crystal layer is between the first and second electrodes, and wherein the first electrode and the second electrode are connected to the electric field applying unit.

16. The device as claimed in claim 15, wherein the light scattering layer includes:
a first passivation layer between the first electrode and the liquid crystal layer; and
a second passivation layer between the second electrode and the liquid crystal layer.

17. A display device, comprising:
a light emitter; and
a light scattering layer to scatter light from the light emitter, wherein the light scattering layer includes a liquid crystal layer which includes cholesteric liquid crystals, the liquid crystal layer coupled to an electric field applying unit, an electric field generated by the electric field applying unit to control a degree to which the light from the light emitter is scattered based on an intensity of the electric field.

18. The device as claimed in claim 17, wherein the electric field is to maintain the cholesteric liquid crystals in a focal conic state.

19. The device as claimed in claim 17, further comprising:
a first electrode;
a second electrode,
wherein the liquid crystal layer is between the first and second electrodes, and wherein the first electrode and the second electrode are connected to the electric field applying unit.

20. The device as claimed in claim 19, wherein the light scattering layer includes:
a first passivation layer between the first electrode and the liquid crystal layer; and
a second passivation layer between the second electrode and the liquid crystal layer.
